(19) United States
(12) Patent Application Publication
(10) Pub. No.: US 2007/0247199 A1
(43) Pub. Date: Oct. 25, 2007

(54) Phase-locked loop apparatus having aligning unit and method using the same

(75) Inventor: Shang-ping Chen, Tai-Chung City (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: MediaTek Inc.

(21) Appl. No.: 11/406,668

(22) Filed: Apr. 19, 2006

(51) Int. Cl. H03D 3/24; H03L 7/06

(52) U.S. Cl. 327/156; 375/376

(57) ABSTRACT

An enhanced phase-locked loop (PLL) apparatus having an aligning unit and method are described. The PLL comprises an aligning unit, a phase difference detecting unit, a charge pump, a loop filter, and a voltage-controlled oscillator. The aligning unit receives a hold signal and a reference signal for shifting an edge of the hold signal to generate the gating signal. The phase difference detecting unit detects a phase difference between the reference signal and a feedback signal and outputting an UP signal and a DOWN signal for representing the phase difference. The edge of the hold signal is aligned to an edge of the reference signal. The charge pump generates a current signal based on the UP and DOWN signals. The loop filter is used to generate a control voltage based on the current signal. The voltage-controlled oscillator receives the control voltage and generates an output signal serving as the feedback signal. The feedback signal is supplied to the optical storage system for generating subsequent data recording signals.

### FIELD OF THE INVENTION

The present invention generally relates to a phase-locked loop apparatus capable of holding the operation in response to a hold signal and method thereof, and more particularly, to a phase-locked loop apparatus having an aligning unit for modifying the duration of the hold signal so that the operation of the phase-locked loop apparatus is resumed at a proper time instant and method using the same.

### BACKGROUND OF THE INVENTION

FIG. 1A is a schematic block diagram of one conventional phase-locked loop (PLL). The PLL mainly includes a phase frequency detector (PFD) 100a, a charge pump 102, a loop filter 104, and a voltage-controlled oscillator 106. A reference signal and a feedback signal are input into the PFD 100a and then an UP or a DOWN signal is output from the PFD 100a. A pair of AND gates 108 receives UP or DOWN signal which are kept by a hold signal. The charge pump 102 then receives the output signals of the AND gates 108 to generate a current signal. The loop filter 104 is connected to the charge pump 102 to generate a control voltage. The voltage-controlled oscillator 106 generates a feedback signal serving as an output signal according to the control voltage.

FIG. 1B shows a schematic timing diagram of the conventional phase-locked loop in FIG. 1A. Four kinds of signals, i.e. a reference signal, a feedback signal, and an UP signal or a DOWN signal, are provided. The horizontal coordinate axis represents time and the vertical coordinate axis represents signal amplitude. A holding window indicates the period during which the reference signal suffers from unstable signal quality. The UP or DOWN signal indicates the phase difference between the reference and the feedback signals. When the reference signal leads the feedback signal, UP signal represents the phase difference between the reference and the feedback signals. Conversely, when the reference signal lags the feedback signal, DOWN signal represents the phase difference between the reference and the feedback signals.

The reference signal may be a wobble signal or an eight-fourteen-modulation (EFM) signal when employed in an optical storage system. In a time period of the holding window, the reference signal bears unstable signal quality while the reference signal experiences poor signal strength or frequency/phase discontinuity. In the time period, the feedback signal will severely lose track of the reference signal, thus the UP and DOWN signal is held to stop the tracking between feedback signal and the reference signal due to improper tracking in this time period. After releasing the holding window, the UP and DOWN signals activates again to resume the tracking between the feedback signal and reference signals. However, around the ending edge of the holding window, the UP and DOWN signals may appear in an abnormal waveform 110 while the holding window ends at an improper time.

FIG. 2A is a schematic block diagram of another conventional phase-locked loop. FIG. 2A is similar to FIG. 1A. The difference between FIG. 1A and FIG. 2A is that a reset (RST) input is provided in the PFD 100b in FIG. 2A for receiving a hold signal, such that the hold signal could be used to reset the PFD 100b. The detailed description is not repeated. FIG. 2B shows a schematic timing diagram of the phase-locked loop in FIG. 2A. Besides, FIG. 2B shows the timing diagram of four signals, including a reference signal, a feedback signal, an UP signal and a DOWN signal, the timing diagram also has a hold signal indicating the unstable periods which are enclosed by the holding window. The duration of the holding window is from the falling edge to the rising edge of the hold signal. Further, after the holding window is released, a phase difference 112 between the hold signal and the reference signal is formed, thereby resulting in alignment failure therebetween.

While an optical disk is recorded during data recording operation, it is necessary to track the wobble signal for detecting the address information, namely the time information. Also, tracking to the EFM signal is necessary in order to detect the data information. The detected address and data information is useful for knowing which of the physical location on the optical disk is available for the subsequent data recording. In a time period, the tracking reference signal, i.e. wobble signal or EFM signal, suffers from unstable signal quality. In the time period, tracking of the feedback signal to the reference signal should be stopped by a holding window for prevention of incorrectly signal tracking, while the ending edge of the holding window also should occur at a proper time for preventing the appearance of abnormal UP and DOWN signals and further preventing the occurrence of erroneous data recording signal.

As aforementioned, conventional PLL, which locks the feedback signal to the reference signal, cannot promise the ending edge of the holding window to be at a proper time, which results in erroneous data recording.

### SUMMARY OF THE INVENTION

One objective of the present invention is to provide a phase-locked loop apparatus having an aligning unit and method for shifting an edge of a hold signal to align to a transition edge of the reference signal.

According to the above objectives, the present invention discloses a phase-locked loop apparatus and method thereof. The phase-locked loop apparatus comprises an aligning unit, a phase difference detecting unit, a charge pump, a loop filter, and a voltage-controlled oscillator. A hold signal is generated to indicate the unstable period of the reference signal. The aligning unit receives the hold signal and the reference signal for shifting an edge of the hold signal to generate the gating signal. The edge of the hold signal is shifted to be aligned to an edge of the reference signal. The phase difference detecting unit receives a reference signal, a feedback signal and the gating signal for detecting a phase difference between the reference signal and the feedback signal and outputting an UP signal and a DOWN signal for representing the phase difference when the gating signal is at HIGH level. The UP and DOWN signals are kept at respective preset logic levels representing a zero phase difference when the gating signal is at LOW level. The charge pump coupled to the phase difference detecting unit generates a current signal based on the UP and DOWN signals. The loop filter coupled to the charge pump is used to generate a control voltage based on the current signal. The voltage-controlled oscillator coupled to the loop filter receives the control voltage and generates an output signal serving as the feedback signal.

In the holding window, the tracking between the reference and the feedback signal is disabled to ignore the phase difference therebetween. After releasing the holding window, the feedback signal immediately catches up with the reference signal. Because the ending edge of the holding window occurs at a proper time, the erroneously data recording will be prevented.

In operation, a phase difference between a reference signal and a feedback signal is detected by a phase difference detecting unit. Then, an UP signal and a DOWN signal for representing the phase difference are output when a gating signal is at HIGH level, and the UP and DOWN signals are kept at respective preset logic levels representing a zero phase difference when the gating signal is at LOW level.

Afterwards, an edge of a hold signal is shifted to generate the gating signal by an aligning unit, where the edge of the hold signal is aligned to an edge of the reference signal. Then, a current signal based on the UP and DOWN signals is generated. A control voltage based on the current signal is generated. An output signal is generated according to the control voltage and serves as the feedback signal.

### BRIEF DESCRIPTION OF THE DRAWINGS

FIG. 1A is a schematic block diagram of a conventional phase-locked loop.

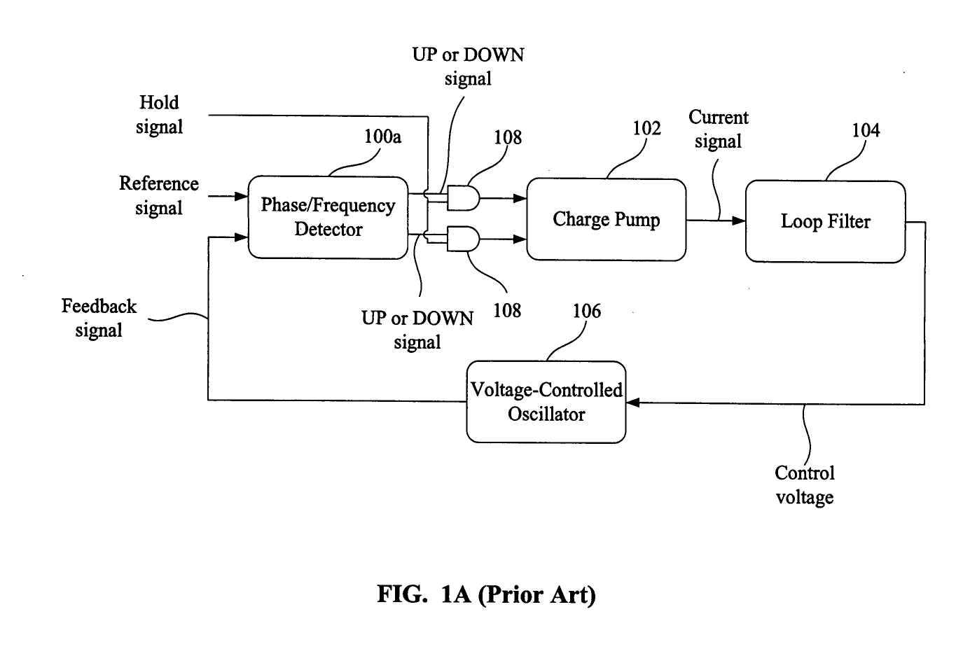

FIG. 1B is a schematic timing diagram of the conventional phase-locked loop in FIG. 1A.

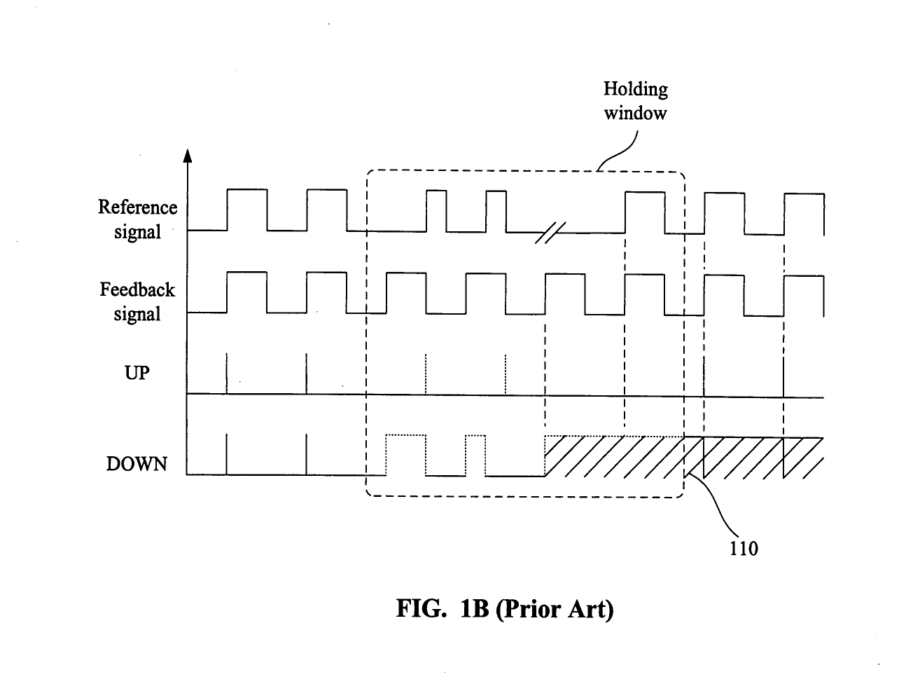

FIG. 2A is a schematic block diagram of another conventional phase-locked loop.

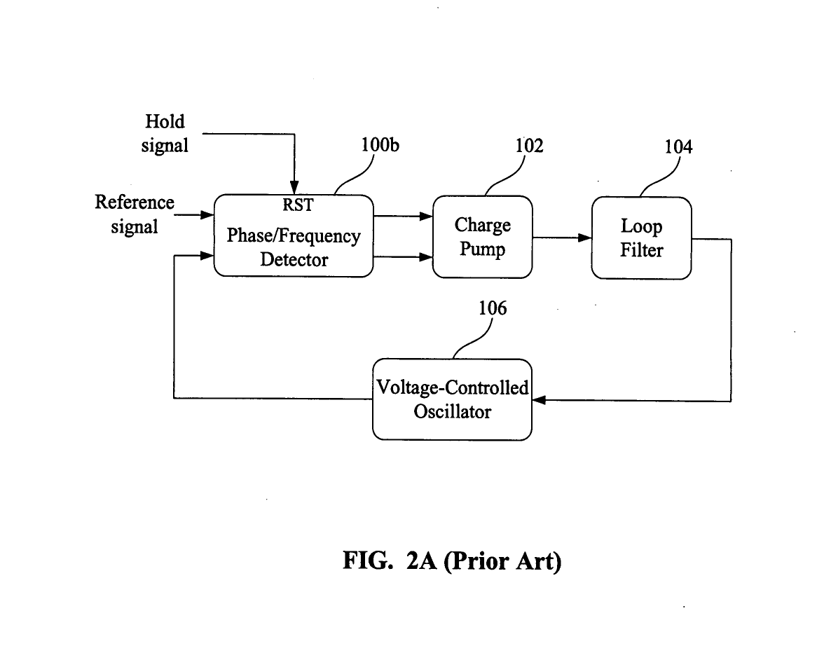

FIG. 2B shows a schematic timing diagram of the conventional phase-locked loop in FIG. 2A.

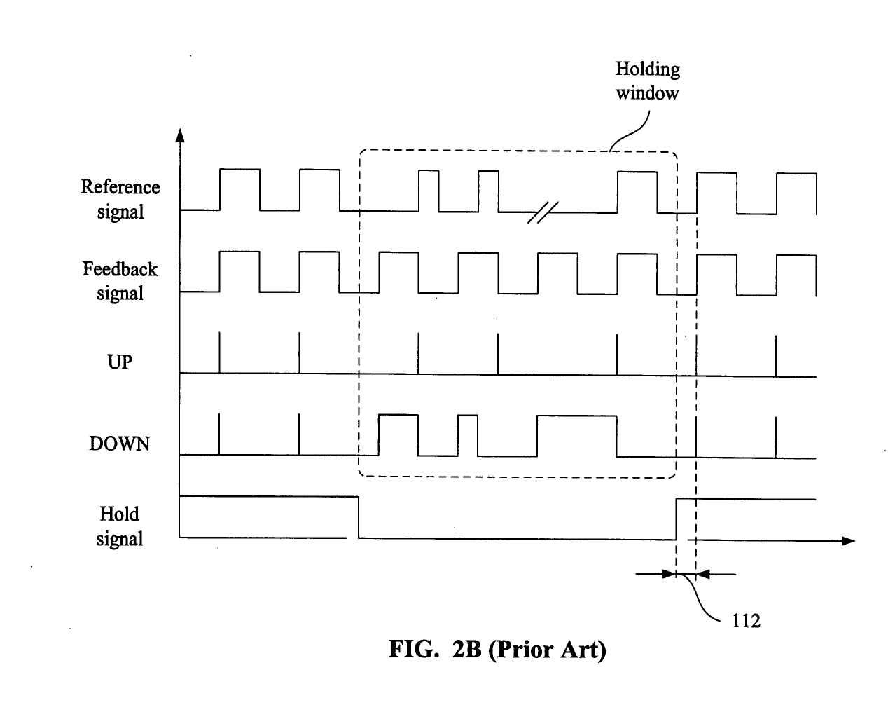

FIG. 3A is a schematic block diagram of a phase-locked loop apparatus with a gating signal supplying to a logic gate according to first embodiment of the present invention.

FIG. 3B is a schematic block diagram of a phase-locked loop apparatus with an aligning unit generating a reset signal to reset a phase difference detecting unit according to second embodiment of the present invention.

FIG. 4 shows a schematic timing diagram of the phase-locked loop apparatus in FIGS. 3A and 3B according to one embodiment of the present invention.

FIG. 5A is a schematic diagram of the aligning unit generating the gating signal in FIGS. 3A and 3B according to one embodiment of the present invention.

FIG. 5B shows a schematic timing diagram of the aligning unit in FIG. 5A.

FIG. 6 shows a flow chart of performing an enhanced PLL.

### DETAILED DESCRIPTION OF THE PREFERRED EMBODIMENTS

The present invention is directed to an phase-locked loop (PLL) appratus having an aligning unit and method for shifting an edge of a hold signal to form a gating signal to precisely align a transition edge of the hold signal to a transition edge of a reference signal. Thus, the PLL is able to solve the problems of tracking a feedback signal to the unstable reference signals and erroneously generating data recording signals for an optical storage system. Moreover, the present invention employs the PLL in an optical storage system to effectively prevent erroneously generated recording signals, which resulted from unstable reference signals and the transition edge of the hold signal occurring at improper time, through gating UP and DOWN signals generated by a phase difference detecting unit. Therefore, the gating signal generated by the aligning unit is utilized to disable the tracking of the feedback signal to the unstable reference signal to promise the quality of the recording signals for the optical storage system.

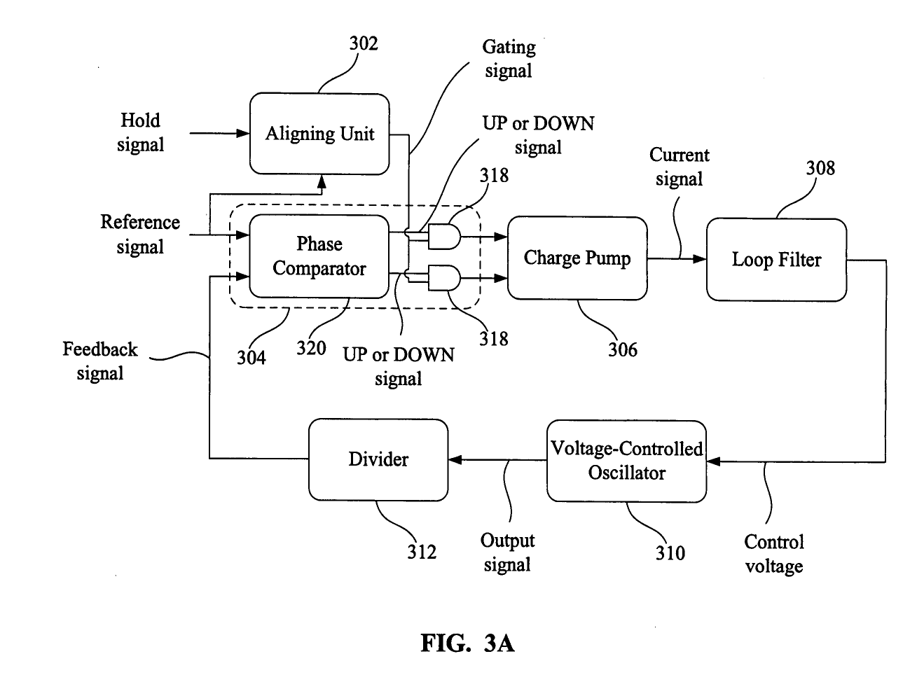

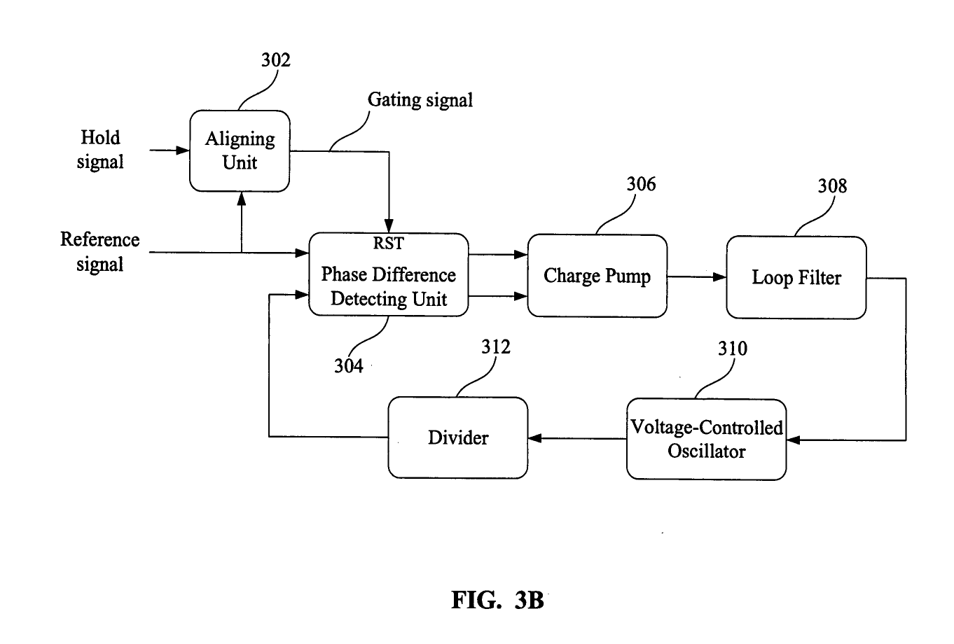

Referring to FIG. 3A, a schematic block diagram of a PLL with an aligning unit generating a gating signal and supplying to a logic gate according to first embodiment of the present invention is shown. The PLL 300 comprises an aligning unit 302, a phase difference detecting unit 304, a charge pump 306, a loop filter 308, and a voltage-controlled oscillator 310. The PLL 300 optionally has a divider 312 to divide the output signal from the voltage-controlled oscillator 310 and form the feedback signal.

A hold signal is generated to indicate the unstable period of the reference signal. The aligning unit 302 receives the hold signal and the reference signal, for shifting a transition edge of the hold signal to be aligned to the transition edge of the reference signal and generating the gating signal.

The phase difference detecting unit 304 receives the reference signal, a feedback signal and the gating signal for detecting a phase difference between the reference signal and the feedback signal and outputting an UP signal and a DOWN signal for representing the phase difference when the gating signal is at HIGH level. The UP and DOWN signals are kept at a respective preset logic level representing a zero phase difference when the gating signal is at LOW level. The preset logic level is logic LOW here in this embodiment. In one preferred embodiment of the present invention, the phase difference detecting unit 304 comprises a phase comparator 320, which is either a phase detector or a phase frequency detector, for generating the UP and DOWN signals.

The charge pump 306 coupled to the phase difference detecting unit 304 generates a current signal based on the UP and DOWN signals. The loop filter 308 coupled to the charge pump 306 is used to generate a control voltage based on the current signal. The voltage-controlled oscillator 310 is coupled to the loop filter 308 for receiving the control voltage and generating an output signal serving as the feedback signal, where the frequency of the output signal is in correspondence with the control voltage.

FIG. 3B is a schematic block diagram of a PLL with a reset signal to reset a phase difference detecting unit 304 according to second embodiment of the present invention. In this embodiment, the phase comparator 320 comprises at least one flip-flop circuit, and the gating signal serves as a reset signal to control the reset (RST) input of the flip-flop circuit. In fact, components in FIG. 3B are similar to components in FIG. 3A except the phase difference detecting unit 304. Therefore, the descriptions of the rest of components in FIG. 3B can be referred to FIG. 3A and are therefore omitted here.

Referring to FIG. 3A again, the phase difference detecting unit 304 further comprises a gating unit 318, connected between the phase difference detecting unit 304 and the charge pump 306, for setting the UP and DOWN signals at respective preset logic levels representing the zero phase difference when the gating signal is at LOW level. In first embodiment of the present invention, the gating unit 318 has a first AND gate and a second AND gate. One input of the first AND gate is coupled to the gating signal and one input of the second AND gate coupled to the gating signal. The other input of the first AND gate and the other input of the second AND gates are coupled to the phase difference detecting unit 304 for respectively receiving the UP and DOWN signals, the outputs of the first and second AND gates are coupled to the charge pump 306.

In second embodiment of the present invention, the gating unit 318 has a first OR gate and a second OR gate. One input of the first OR gate is coupled to the gating signal. One input of the second OR gate is coupled to the gating signal. The other input of the first OR gate and the other input of the second OR gate are coupled to the phase difference detecting unit 302a for respectively receiving the UP and DOWN signal, the outputs of the first and second OR gates are coupled to the charge pump 306. It should be noted that the logic components connected to the gating unit 318 can comprise any type of logic gates or the combination thereof, such that the requirement of the logic level of the gating signal is subject to the logic components.

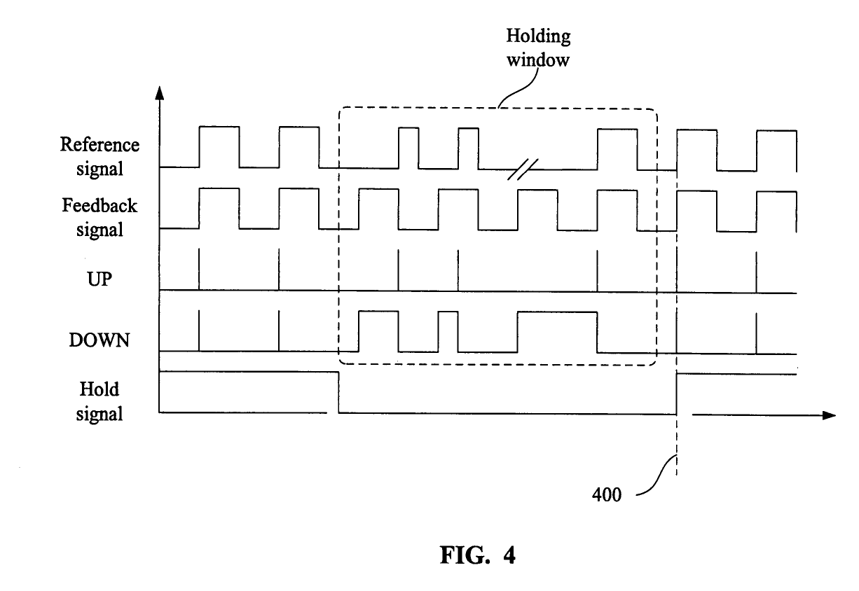

FIG. 4 shows a schematic timing diagram of the PLL in FIGS. 3A and 3B according to one embodiment of the present invention. In this embodiment, the rising edge of the hold signal is shifted to be aligned to the rising edge of the reference signal, as indicated by number 400. While the rising edge of the hold signal is aligned, there are no abnormal UP and DOWN signals. That is, after the holding window is released, the feedback signal immediately catches up with the reference signal, for no misleading of the feedback signal tracking to the reference signal has ever occurred.

In the holding period indicated by the hold signal, the tracking of the feedback signal to the reference signal is stopped to ignore the phase difference therebetween. After the holding period, the feedback signal starts again to catch up with the reference signal to resolve the phase difference therebetween.

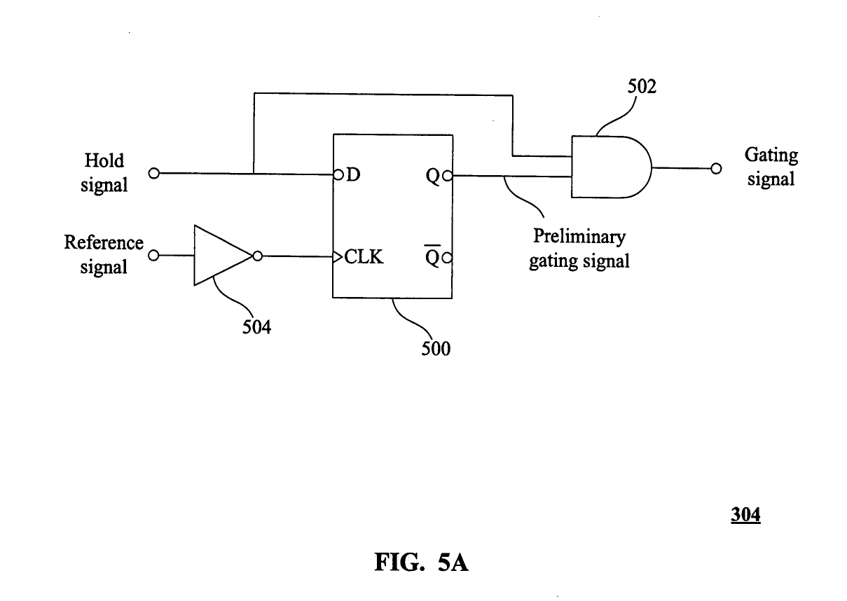

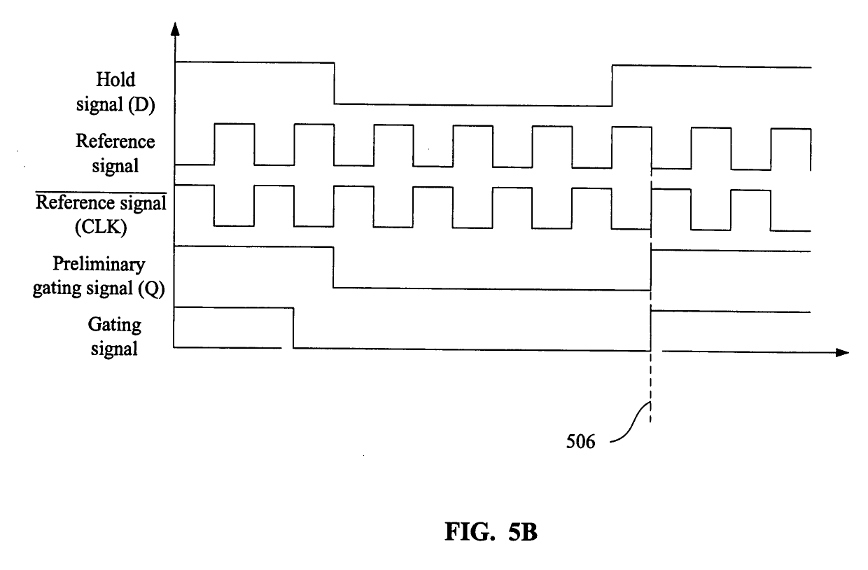

FIG. 5A is a schematic diagram of the aligning unit generating the gating signal in FIGS. 3A and 3B according to one embodiment of the present invention and FIG. 5B shows a schematic timing diagram of the aligning unit in FIG. 5A. The aligning unit 302 comprises a flip-flop circuit 500 and an AND gate 502. The flip-flop circuit 500 receives the hold signal and is clocked by the reference signal to generate a preliminary gating signal. The AND gate 502 receives the hold signal and the preliminary gating signal from output Q of the flip-flop circuit 500 to generate the gating signal. In one embodiment, the AND gate 502 can also be replaced with an OR gate which receives the hold signal and the preliminary gating signal to generate the gating signal.

Alternatively, the aligning unit 302 comprises a flip-flop circuit 500 and an AND gate 502, which the flip-flop circuit 500 receives the hold signal and is clocked by an inversed version of the reference signal to generate a preliminary gating signal. For example, the reference signal is first input into a NOT gate 504 and then transmitted to the clocked input of the flip-flop circuit 500. The AND gate 502 receives the hold signal and the preliminary gating signal from output Q of the flip-flop circuit 500 to generate the gating signal. The AND gate 502 can be replaced with an OR gate which receives the hold signal and the preliminary gating signal to generate the gating signal.

In FIG. 5B, a timing diagram of the aligning unit 304 in FIG. 5A is illustrated. In this embodiment, the falling edge of the gating signal may be or not be exactly aligned to the preliminary gating signal or the hold signal and, however, the rising edge of the gating signal is preferably aligned to the edge of the reference signal, as indicated by number 506, upon the rising edge of the hold signal occurs. Therefore, the gating signal generated by the aligning unit 302 is utilized to disable the tracking of the feedback signal to the unstable reference signal to promise the quality of the recording signal.

Preferably, the optical disk comprises a write-once optical disk, such as a CD-R (Compact Disk-Recordable), and a DVD-R (Digital Versatile Disk-Recordable), and a rewritable optical disk, such as a CD-RW (CD-Rewritable), a DVD-RW (DVD-Rewritable), a DVD-RAM, an MO (Magneto Optical disk), and the like.

Since the optical storage system roughly predicts the holding period having unstable quality of reference signals. In the present invention, the holding period is further adjusted for the alignment of the transition edge of the reference signal. The edge aligned holding period prevents the feedback signal from incorrectly tracking the reference signal, and also prevent the occurrence of abnormal UP and DOWN signals. The edge aligned holding period is generated by the aligning unit 302 and indicated by the gating signal. The gating signal is utilized to disable the tracking between the feedback signal and the reference signal, thus preventing the erroneously generated recording signal for the optical storage system.

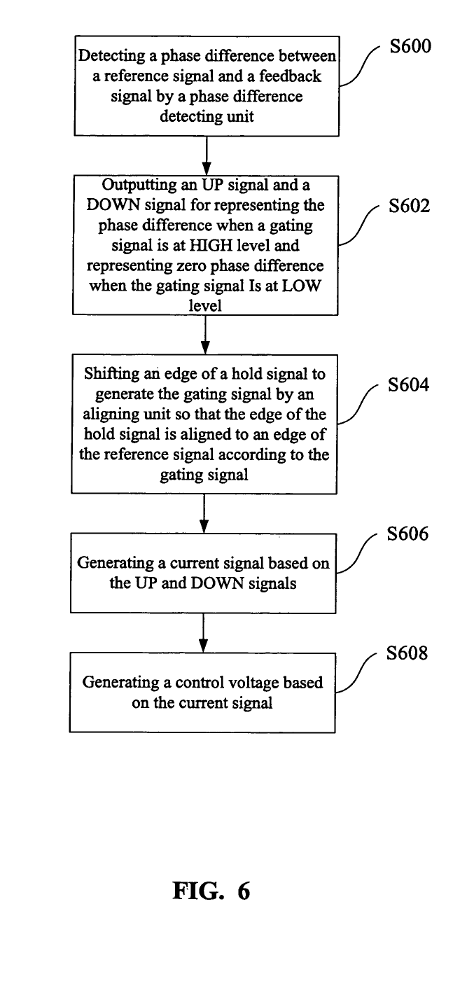

FIG. 6 shows a flow chart of performing a PLL. Starting at step S600, a phase difference between a reference signal and a feedback signal is detected by a phase difference detecting unit. Then, in step S602, an UP signal and a DOWN signal for representing the phase difference are output when a gating signal is at HIGH level, and the UP and DOWN signals are kept at a respective preset logic level representing a zero phase difference when the gating signal is at LOW level. In step S604, an edge of a hold signal is shifted to generate the gating signal by an aligning unit, where the edge of the hold signal is aligned to an edge of the reference signal. Then, in step S606, a current signal based on the UP and DOWN signals is generated. Afterward, in step S608, a control voltage based on the current signal is generated.

During the step of shifting the edge of the hold signal in step S604, a flip-flop circuit receives the hold signal and is clocked by the reference signal to generate a preliminary gating signal. Then, an AND gate receives the hold signal and the preliminary gating signal to generate the gating signal. After the step of generating the control voltage based on the current signal, an output signal is generated to serve as the feedback signal, where the frequency of the output signal is in correspondence with the control voltage. In step S608, the generation of the control voltage also comprises filtering the current signal.

Consequently, the present invention can solve the problem of the appearance of abnormal UP and DOWN signals around the ending edge of the holding window. Further the erroneously generated data recording signals are also prevented because of the alignment of the holding window.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A phase-locked loop apparatus, comprising:
an aligning unit receiving a hold signal and a reference signal, for shifting an edge of the hold signal to form a gating signal, wherein the edge of the hold signal is shifted to be aligned to an edge of the reference signal;
a phase difference detecting unit receiving the reference signal, a feedback signal and the gating signal, for detecting a phase difference between the reference signal and the feedback signal and outputting an UP signal and a DOWN signal for representing the phase difference when the gating signal is at a first logic level, and the UP and DOWN signals are kept at respective preset logic levels representing a zero phase difference when the gating signal is at a second logic level;
a charge pump coupled to the phase difference detecting unit, for generating a current signal based on the UP and DOWN signals;
a loop filter coupled to the charge pump, for generating a control voltage based on the current signal; and
a voltage-controlled oscillator coupled to the loop filter, for generating an output signal having a frequency in correspondence with the control voltage, wherein the output signal serves as the feedback signal which is input into the phase difference detecting unit.

2. The phase-locked loop apparatus of claim 1, wherein the edge of the reference signal is a rising edge.

3. The phase-locked loop apparatus of claim 1, wherein the edge of the reference signal is a falling edge.

4. The phase-locked loop apparatus of claim 1, wherein the phase difference detecting unit comprises a phase comparator, which is either a phase detector or a phase frequency detector, for generating the UP and DOWN signals.

5. The phase-locked loop apparatus of claim 4, wherein the phase comparator comprises at least one flip-flop circuit, and the gating signal serves as a reset signal to reset the at least one flip-flop circuit.

6. The phase-locked loop apparatus of claim 4, wherein the phase difference detecting unit further comprises a gating unit, connected between the phase comparator and the charge pump, for receiving the gating signal and setting the UP and DOWN signals at respective preset logic levels representing the zero phase difference when the gating signal is at the second logic level.

7. The phase-locked loop apparatus of claim 6, wherein the gating unit comprises:
a first AND gate, one input of the first AND gate coupled to the gating signal; and
a second AND gate, one input of the second AND gate coupled to the gating signal;
wherein the other input of the first AND gate and the other input of the second AND gate are coupled to the phase comparator for respectively receiving the UP and DOWN signals, the outputs of the first and second AND gates are coupled to the charge pump.

8. The phase-locked loop apparatus of claim 6, wherein the gating unit comprises:
a first OR gate, one input of the first OR gate coupled to the gating signal; and
a second OR gate, one input of the second OR gate coupled to the gating signal;
wherein the other input of the first OR gate and the other input of the second OR gates are coupled to the phase comparator for respectively receiving the UP and DOWN signals, the outputs of the first and second OR gates are coupled to the charge pump.

9. The phase-locked loop apparatus of claim 1, wherein the aligning unit comprises:
a flip-flop circuit, receiving the hold signal and being clocked by the reference signal to generate a preliminary gating signal; and
an AND gate, receiving the hold signal and the preliminary gating signal to generate the gating signal.

10. The phase-locked loop apparatus of claim 1, wherein the aligning unit comprises:
a flip-flop circuit, receiving the hold signal and being clocked by the reference signal to generate a preliminary gating signal; and
an OR gate, receiving the hold signal and the preliminary gating signal to generate the gating signal.

11. The phase-locked loop apparatus of claim 1, wherein the aligning unit comprises:
a flip-flop circuit, receiving the hold signal and being clocked by an inversed version of the reference signal to generate a preliminary gating signal; and
an AND gate, receiving the hold signal and the preliminary gating signal to generate the gating signal.

12. The phase-locked loop apparatus of claim 1, wherein the aligning unit comprises:
a flip-flop circuit, receiving the hold signal and being clocked by an inversed version of the reference signal to generate a preliminary gating signal; and
an OR gate, receiving the hold signal and the preliminary gating signal to generate the gating signal.

13. A method of performing a phase-locked loop in an optical storage system, the method comprising the steps of:
detecting a phase difference between a reference signal and a feedback signal and outputting an UP signal and a DOWN signal for representing the phase difference when a gating signal is at a first logic level, and the UP and DOWN signals are kept at respective preset logic levels representing a zero phase difference when the gating signal is at a second logic level; and
shifting an edge of a hold signal to generate the gating signal, wherein the edge of the hold signal is shifted to be aligned to an edge of the reference signal.

14. The method of claim 13, wherein the edge of the reference signal is a rising edge.

15. The method of claim 13, wherein the edge of the reference signal is a falling edge.

16. The method of claim 13, during the step of shifting the edge of the hold signal to generate the gating signal, comprising the steps of:
flip-flopping the hold signal which is clocked by the reference signal to generate a preliminary gating signal; and
generating the gating signal by performing an AND operation on the hold signal and the preliminary gating signal.

17. The method of claim 13, during the step of shifting the edge of the hold signal to generate the gating signal, comprising the steps of:
flip-flopping the hold signal which is clocked by the reference signal to generate a preliminary gating signal; and
generating the gating signal by performing an OR operation on the hold signal and the preliminary gating signal.

18. The method of claim 13, during the step of shifting the edge of the hold signal to generate the gating signal, comprising the steps of:
flip-flopping the hold signal which is clocked by an inversed version of the reference signal to generate a preliminary gating signal; and
generating the gating signal by performing an AND operation on the hold signal and the preliminary gating signal.

19. The method of claim 13, during the step of shifting the edge of the hold signal to generate the gating signal, comprising the steps of:
flip-flopping the hold signal which is clocked by an inversed version of the reference signal to generate a preliminary gating signal; and
generating the gating signal by performing an OR operation on the hold signal and the preliminary gating signal.

20. The method of claim 13, after the step of shifting the edge of the hold signal, further comprising the steps of:
generating a current signal based on the UP and DOWN signals; and
generating a control voltage based on the current signal.

21. The method of claim 20, during the step of generating the control voltage based on the current signal, further comprising filtering the current signal.

22. The method of claim 20, after the step of generating the control voltage based on the current signal, further comprising generating an output signal having a frequency in correspondence with the control voltage, wherein the output signal serves as the feedback signal.
